(19) United States
(12) Patent Application Publication
(10) Pub. No.: US 2025/0385648 A1
(43) Pub. Date: Dec. 18, 2025

(54) INPUT BUFFER AND OPERATION METHOD THEREOF

(71) Applicant: MACRONIX INTERNATIONAL CO., LTD., HSINCHU (TW)

(72) Inventors: Tung-Yu LI, Taoyuan City (TW); Shang-Chi YANG, Changhua County (TW)

(21) Appl. No.: 18/743,325

(22) Filed: Jun. 14, 2024

(51) Int. Cl. H03F 1/42; H03F 1/02; H03F 3/45

(52) U.S. Cl. CPC H03F 1/42; H03F 1/0211; H03F 3/45183; H03F 2200/36

(57) ABSTRACT

An input buffer includes first to second amplifiers. The first amplifier includes a first front-end circuit, a first transistor, and a second transistor, and receives first and second voltages. First terminals of the first to second transistors are coupled with the first front-end circuit at first and second nodes respectively. A second terminal of the second transistor is coupled with a second terminal of the first transistor at a reference node. The first amplifier outputs, in response to the first and second voltages, third and fourth voltages at the first and second nodes, respectively. The second amplifier includes a third transistor and a fourth transistor. Control terminals of the third and fourth transistors are coupled with the first amplifier at the first and second nodes, respectively. The second amplifier generates a fifth voltage in response to the third voltage and the fourth voltage.

### RELATED APPLICATIONS

### BACKGROUND

### TECHNICAL FIELD

The present application relates to an input buffer and a method for operating the same. More particularly, the present application relates to an input buffer having multiple amplifiers and capability of receiving broadband signals and a method for operating the same.

### DESCRIPTION OF RELATED ART

Signals decay while being sent in a channel from a transmitting device to a receiving device. When the channel loss cannot be compensated, another route to solve this problem is to amplify signals before using them. In addition, the signal rate of reliable communication is directly proportional to the communication bandwidth according to the Shannon-Hartley theorem. If there is no enough bandwidth, the signals cannot be received completely for high speed signal transmission. Broadening the bandwidth is an important issue in the field of communication as well. Therefore, the present invention is devoted to develop a broadband buffer to solve the problem of the channel loss and the insufficient bandwidth.

### SUMMARY

An input buffer is provided and includes first to second amplifiers. The first amplifier includes a first front-end circuit, a first transistor, and a second transistor. The first front-end circuit is configured to receive a first voltage and a second voltage. A first terminal of the first transistor is coupled with the first front-end circuit at a first node. A first terminal of the second transistor is coupled with the first front-end circuit at a second node. A second terminal of the second transistor is coupled with a second terminal of the first transistor at a reference node. The first amplifier is configured to output, in response to the first voltage and second voltage, a third voltage and a fourth voltage at the first node and the second node, respectively. The second amplifier includes a third transistor and a fourth transistor. A control terminal of the third transistor and a control terminal of the fourth transistor are coupled with the first amplifier at the first node and the second node, respectively. The second amplifier is configured to generate a fifth voltage in response to the third voltage and the fourth voltage.

In some embodiments, the first amplifier further includes a first resistor coupled between the first node and a control terminal of the first transistor and a second resistor coupled between the second node and a control terminal of the second transistor.

In some embodiments, the first resistor and the second resistor have the same value.

In some embodiments, the first transistor and the second transistor are of the same conductivity type.

In some embodiments, both the first transistor and the second transistor have a first threshold voltage.

In some embodiments, the first front-end circuit includes a transistor pair. A plurality of control terminals of the transistor pair are configured to receive the first voltage and the second voltage. A plurality of first terminals of the transistor pair are coupled with each other.

In some embodiments, a second threshold voltage of each transistor of the transistor pair is larger than the first threshold voltage.

In some embodiments, the third transistor and the fourth transistor are of the same conductivity type.

In some embodiments, the second amplifier further includes a fifth transistor and a sixth transistor. A first terminal of the fifth transistor is coupled with a first terminal of the third transistor at a third node. A first terminal of the sixth transistor is coupled with a first terminal of the fourth transistor at a fourth node. A second terminal of the fifth transistor and a second terminal of the sixth transistor are coupled with each other.

In some embodiments, the second amplifier further includes a seventh transistor. A first terminal of the seventh transistor is coupled with a second terminal of the fourth transistor. A second terminal of the seventh transistor is coupled to the reference node. A control terminal of the seventh transistor is coupled with a control terminal of the fifth transistor and a control terminal of the sixth transistor at the third node.

In some embodiments, the input buffer further includes at least one third amplifier coupled to the first amplifier through first and second terminals of the at least one third amplifier, and configured to generate, in response to a corresponding sixth to seventh voltages received by a second front-end circuit thereof, signals to the first amplifier for generating the first to second voltages. The at least one third amplifier comprises fifth to sixth transistors coupled to the second front-end circuit at the first and second terminals of the at least one third amplifier.

In some embodiments, the second front-end circuit comprises a seventh transistor and an eighth transistor, and the seventh transistor and the eighth transistor, the third transistor, and the fourth transistor are of the same conductivity type.

An input buffer is provided and includes a front-end circuit coupled with a current source, first to fourth transistor, and a current control unit. A drain terminal of the first transistor is coupled with the front-end circuit at a first node. A drain terminal of the second transistor is coupled with the front-end circuit at a second node. A source terminal of the second transistor and a source terminal of the first transistor are coupled with each other at a reference node. A gate terminal of the third transistor is coupled to the first node. A drain terminal of the third transistor is coupled with a first output terminal of a bias supply circuit at a third node. A gate terminal of the fourth transistor is coupled to the second node. A drain terminal of the fourth transistor is coupled with a second output terminal of the bias supply circuit at a fourth node. The current control unit is coupled with a source terminal of the third transistor and a source terminal of the fourth transistor at a fifth node, and configured to control a total current flowing through the third transistor and the fourth transistor.

In some embodiments, the first to fourth transistors are of the same conductivity type.

In some embodiments, both the first transistor and the second transistor have a first size. Both the third transistor and the fourth transistor have a second size which is different from the first size.

In some embodiments, the second size is larger than the first size.

In some embodiments, the current control unit includes a fifth transistor. A drain terminal of the fifth transistor is coupled to the fifth node. A source terminal of the fifth terminal is coupled to the reference node. A gate terminal of the fifth transistor is coupled to the third node.

An operation method of an input buffer is provided and includes applying a current supplied by a current source to a front-end circuit of a first amplifier, and generating, by the front-end circuit, a first current flowing through a first active inductor circuit and a second current flowing through a second active inductor circuit in response to a first voltage and a second voltage; and generating, by a second amplifier, a third current flowing through a third transistor and a fourth current flowing through a fourth transistor in response to a third voltage associated with the first current and a fourth voltage associated with the second current, and outputting, by the second amplifier, a fifth voltage according to the fourth current.

In some embodiments, the first active inductor circuit and the second active inductor includes a first transistor and a second transistor, respectively. A current ratio of the third current to the first current is associated with a size ratio of a first size of the third transistor to a second size of the first transistor.

In some embodiments, the operation method the input buffer further includes applying a voltage supplied by a voltage source to a bias supply circuit to output a bias voltage between a drain terminal of the first transistor and a drain terminal of the second transistor.

### BRIEF DESCRIPTION OF THE DRAWINGS

The disclosure can be more fully understood by reading the following detailed description of the embodiment, with reference made to the accompanying drawings as follows:

FIG. 1 is a schematic diagram of signal transmission between a transmitting device and a receiving device, in accordance with some embodiments of the present disclosure.

FIG. 2A is a circuit diagram of an input buffer, in accordance with some embodiments of the present disclosure.

FIG. 2B is a circuit diagram of an input buffer, in accordance with some embodiments of the present disclosure; and

FIG. 3 is a schematic diagram of an input buffer, in accordance with some embodiments of the present disclosure.

FIG. 4 illustrates a flow chart of an operation method of a memory device corresponding to FIGS. 1-3, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Reference throughout the specification to "one embodiment," "an embodiment," or “some embodiments” means that a particular feature, structure, implementation, or characteristic described in connection with the embodiment(s) is included in at least one embodiment of the present disclosure. Thus, uses of the phrases "in one embodiment" or "in an embodiment" or “in some embodiments” in various places throughout the specification are not necessarily all referring to the same embodiment. Furthermore, the particular features, structures, implementation, or characteristics may be combined in any suitable manner in one or more embodiments.

As used herein, “around”, “about”, “approximately” or “substantially” shall generally refer to any approximate value of a given value or range, in which it is varied depending on various arts in which it pertains, and the scope of which should be accorded with the broadest interpretation understood by the person skilled in the art to which it pertains, so as to encompass all such modifications and similar structures. In some embodiments, it shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated, or meaning other approximate values.

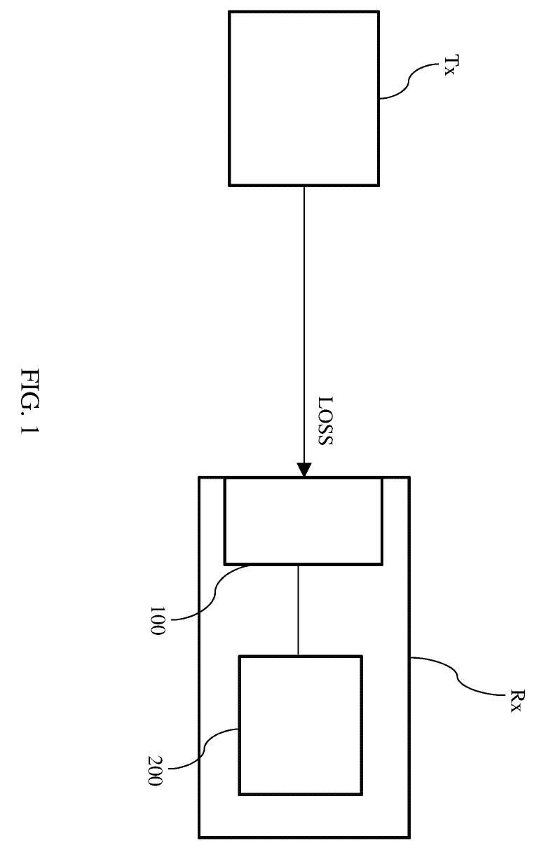

Reference is now made to FIG. 1. FIG. 1 is a schematic diagram of signal transmission between a transmitting device Tx and a receiving device Rx, in accordance with some embodiments of the present disclosure. As shown in FIG. 1, the transmitting device Tx is configured to send one or more signals to the receiving device Rx. The receiving device Rx includes an input buffer 100 and a working device 200 electrically connected with the input buffer 100. In some embodiments, the working device includes logic operation circuits, analog circuits, or other suitable internal integrated circuit.

In some embodiments, the input buffer 100 is configured to amplify signals received from the transmitting device Tx and then to transmit them to the working device 200 for utilization in order to solve the problem of the signal decrease caused by the channel loss.

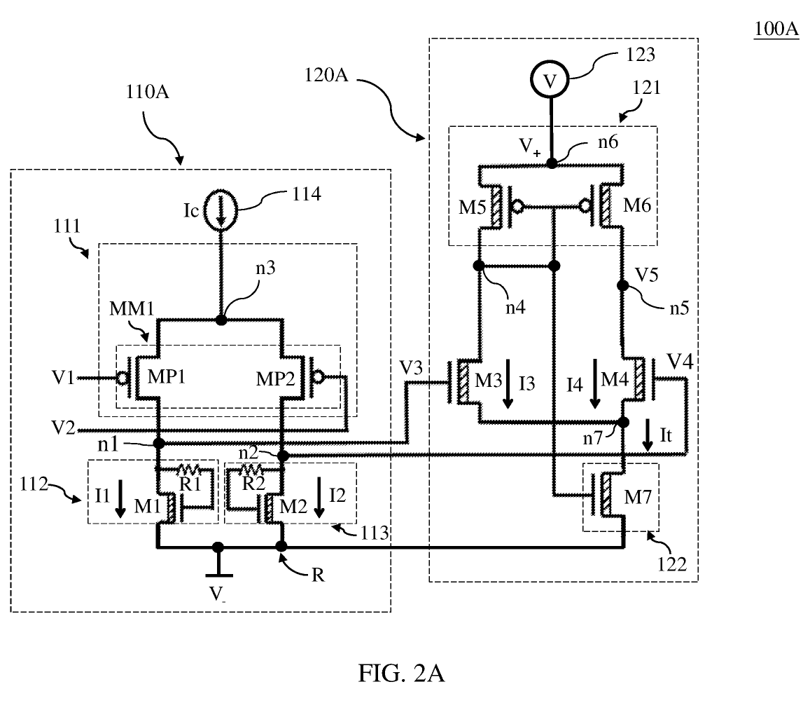

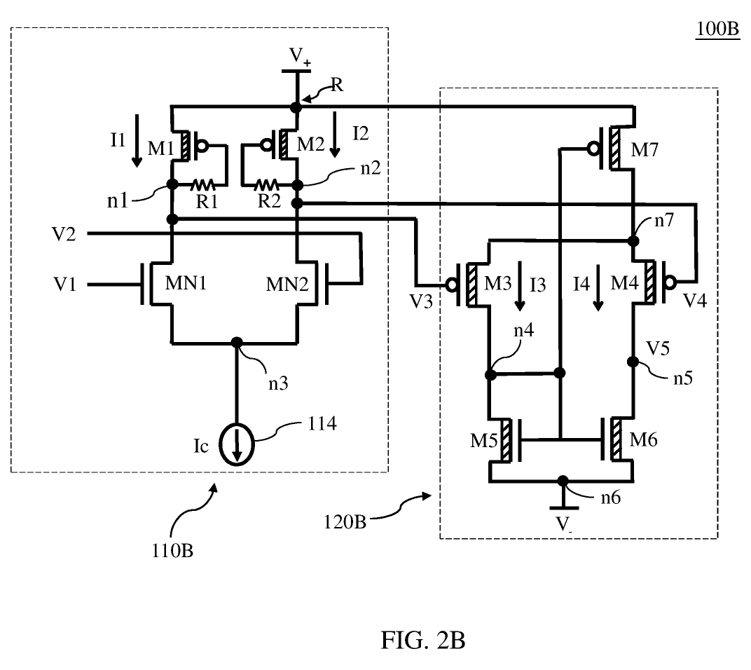

Reference is now made to FIG. 2A. FIG. 2A is a circuit diagram of an input buffer, in accordance with some embodiments of the present disclosure. In some embodiments, the input buffer 100A is configured with respect to, for example, the input buffer 100 of FIG. 1. As shown in FIG. 2A, the input buffer 100A includes an amplifier 110A and an amplifier 120A. Specifically, the amplifier 110A includes a front-end circuit 111, an active inductor circuit 112, an active inductor circuit 113 and a current source 114 coupled with the front-end circuit 111. The amplifier 120A includes a bias supply circuit 121, a transistor M3, a transistor M4, a current control unit 122 and a voltage source 123 coupled to the bias supply circuit 121. A drain terminal of the transistor M3 and a drain terminal of the transistor M4 are coupled with the bias supply circuit 121 at a node n4 and a node n5, respectively, and the current control unit 122 is coupled with a source terminal of the transistor M4 and a source terminal of the transistor M3 at a node n7. In addition, one terminal of the active inductor circuit 112, one terminal of the active inductor circuit 113, and one terminal of the current control unit 122 are coupled to a reference node R having a voltage V₋. In some embodiments, the reference node R is a ground terminal and the voltage V₋ is a ground voltage.

In some embodiments, the transistor M3 and the transistor M4 are of the same conductivity type, for example, the N-type metal-oxide-semiconductor field-effect transistors (MOS).

In some embodiments, as shown in FIG. 2A, the front-end circuit 111 is configured to receive a voltage V1 and a voltage V2 corresponding to signals from the transmitting device Tx. Specifically, the front-end circuit 111 includes a transistor pair MM1 composed of a transistor MP1 and a transistor MP2. Two gate terminals (namely, two control terminals) of the transistor pair MM1 are configured to receive the voltage V1 and the voltage V2. In some embodiments, the transistor MP1 and the transistor MP2 are of the same conductivity type, for example, the P-type MOSs.

As shown in FIG. 2A, the active inductor circuit 112 includes a resistor R1 and a transistor M1. The resistor R1 is coupled between a gate terminal and a drain terminal of the transistor M1. The drain terminal of the transistor M1 is coupled with the front-end circuit 111 at a node n1.

The active inductor circuit 113 includes a resistor R2 and a transistor M2. The resistor R2 is coupled between a gate terminal and a drain terminal of the transistor M2. The drain terminal of the transistor M2 is coupled with the front-end circuit 111 at a node n2.

In some embodiments, the transistor M1 and the transistor M2 are of the same conductivity type, for example, the N-type MOSs. In some embodiments, the transistors M1-M4 are of the same conductivity type.

As shown in FIG. 2A, the amplifier 110A is coupled with the amplifier 120A through the node n1 and the node n2. Specifically, the front-end circuit 111 and the active inductor circuit 112 are coupled with a gate terminal of the transistor M3 at the node n1. The front-end circuit 111 and the active inductor circuit 113 are coupled with a gate terminal of the transistor M4 at the node n2. Alternatively stated, it is the connection relationship between the amplifier 110A and the amplifier 120A: the gate terminal of the transistor M3 is coupled with the drain terminal of the transistor M1 at the node n1, and the gate terminal of the transistor M4 is coupled with the drain terminal at the node n2.

With such configurations, the amplifier 110A generates a voltage V3 and a voltage V4 at the node n1 and the node n2, respectively, according to the received voltage V1 and voltage V2, and outputs the voltage V3 and the voltage V4 to the gate terminal of the transistor M3 and the gate terminal of the transistor M4, respectively. Then, the amplifier 120A generates a voltage V5 at a node n5 according to the received voltage V3 and voltage V4.

Specifically, the transistor MP1 and the transistor MP2 response to the voltage V1 and the voltage V2, respectively, to generate a current I1 flowing through the transistor M1 and a current I2 flowing through the transistor M2 according to a current Ic. Then, the amplifier 110A outputs the voltage V3 associated with the current I1 to the transistor M3 to control the current I3 flowing through the transistor M3. Similarly, the amplifier 110A outputs the voltage V4 associated with the current I2 to the transistor M4 to control the current I4. Then, the amplifier 120A outputs the voltage V5 associated with the current I4.

In comparison with some implementations, the bandwidth of the signals to be transmitted by the input buffer 100A can be broadened through the configurations provided by the present disclosure. The gate terminal of the transistor M3 provides a capacitor C_{L} (not show in drawings) connected in parallel between the drain terminal and the source terminal of the transistor M1 while a parasitic capacitor of the transistor M1 itself is provided as a capacitor Cgs (not show in drawings) connected in parallel between the gate terminal and the source terminal thereof. The capacitor C_{L} in combination with the resistor R1 provides a pole while the capacitor Cgs in combination with the resistor R1 provides a zero. By utilizing the pole-zero compensation, the bandwidth is broadened. Similarly, these configurations associated with the transistor M2 and the transistor M4 has the effect of broadening the bandwidth as well.

In this way, the bandwidth can be increased to two to three times. In some embodiments, the bandwidth is originally in the range of 1-2GHz. Through the pole-zero compensation, the bandwidth becomes 3-5GHz. On the other hand, when the resistors R1-R2 are zero, the pole-zero compensation disappears and there is no effect of broadening the bandwidth. Therefore, in some embodiments, adjustable resistors can be selected as the resistor R1 and the resistor R2 and the values of the Resistor R1 and the Resistor R2 are adjustable according to requirements to turn the bandwidth into the required one.

In addition, through the configurations provided by the present disclosure, the current I3 flowing through the transistor M3 is limited by the current I1 flowing the transistor M1, and the current I4 flowing through the transistor M4 is limited by the current I2 flowing the transistor M1. Thus, it prevents the amplifier 120A from excessive power consumption.

More particularly, the bias supply circuit 121 includes a transistor M5 and a transistor M6. The drain terminal of the transistor M5 is coupled with the drain terminal of the transistor M3 at the node n4. The drain terminal of the transistor M6 is coupled with the drain terminal of the transistor M4 at the node n5. The source terminal of the transistor M5 and the source terminal of the transistor M6 are coupled with each other at a node n6. The bias supply circuit 121 receives a voltage V₊ provided by the voltage source 123 at the node n6 and correspondingly outputs a bias voltage between the drain terminal of the transistor M3 and the drain terminal of the transistor M4. In some embodiment, the voltage V₊ is larger than the voltage V₋ of the reference node R. In addition, in some embodiments, the transistor M5 and the transistor M6 are of the same conductivity type.

More particularly, the current control unit 122 is configured to control the sum of the current I3 and the current I4, that is, a total current It flowing through the transistor M3 and the transistor M4. In some embodiments, the current control unit 122 includes a transistor M7. A drain terminal, a source terminal, and a gate terminal of the transistor M7 are coupled to the node n7, the reference node R, and the node n4, respectively. In some embodiments, the gate terminal of the transistor M7 is coupled with a gate terminal of the transistor M5 and the transistor M6 at the node n4. In addition, in some embodiments, the transistor M7 is an N-type MOS.

Reference is now made to FIG. 2B. FIG. 2B is a circuit diagram of an input buffer 100B, in accordance with some embodiments of the present disclosure. In some embodiments, the input buffer 100B is configured with respect to, for example, the input buffer 100. In comparison with the embodiments in FIG. 2A, for being understood easily, similar components are labeled by using the same reference numerals. For the sake of conciseness, specific operation for similar components that is already detailed in the preceding paragraphs is omitted herein unless there is a need to introduce the cooperation with the components in FIG. 2B.

In comparison with FIG. 2A, the transistors MN1, MN2, M5, M6 of the input buffer 100B are of N-type, and the transistors M1, M2, M3, M4, M7 are of P-type. The reference node R has the voltage V₊. Furthermore, the node n6 is configured to receive the voltage V₋. In some embodiments, the voltage V₋is smaller than the voltage V₊. In other embodiments, the reference node R is a ground terminal and the voltage V₋ is a ground voltage.

The embodiments as mentioned above merely serve the goal of understanding the main idea of the present disclosure easily and do not limit the scope of the present disclosure. The conductivity type of each transistor of the input buffer 100 as mentioned above can be determined according to requirements.

In addition, the size of each transistor of the input buffer 100 can be determined according to requirements as well. For example, the width of the gate terminal of each transistor is selected as the size thereof. In some embodiments, the sizes of the transistor M1 and the transistor M2 are the same: both they have a size W1. In some embodiments, the sizes of the transistor M3 and the transistor M4 are the same: both they have a size W2. In some embodiments, both the transistor M1 and the transistor M2 have the size W1 and both the transistor M3 and the transistor M4 have the size W2. In some embodiments, the size W2 is equal to the size W1. In other embodiments, the size W2 is further larger than the size W1, for example, the size W2 is one to two times the size W1. A size ratio of the size W2 to the size W1 limits the maximum of a current ratio of the current I3 to the current I1 and the maximum of a current ratio of the current I4 to the current I2. For example, the current I3 is not larger than the current I1 and the current I4 is not larger than the current I2. For another example, the current I3 is not larger than two times the current I1 and the current I4 is not larger than two times the current I2 when the size W2 is two times the size W1. In some embodiments, the transistor M1, the transistor M2, the transistor M3, and the transistor M4 have a size W1-1, a size W1-2, a size W2-1, and a size W2-2, respectively, and the size W1-1, the size W1-2, the size W2-1, and the size W2-2 can be different from each other. Similarly, a size ratio of the size W2-1 to the size W1-1 limits the maximum of a current ratio of the current I3 to the current I1, and a size ratio of the size W2-2 to the size W1-2 limits the maximum of a current ratio of the current I4 to the current I2. Alternatively stated, the current ratio of the current I3 to the current I1 is associated with the size ratio of the size W2-1 to the size W1-1, and the current ratio of the current I4 to the current I2 is associated with the size ratio of the size W2-2 to the size W1-2.

In some embodiments, both the transistor M1 and the transistor M2 have a threshold voltage Vth1. In some embodiments, a threshold voltage Vth2 of each transistor of the transistor pair MM1 is larger than the threshold voltage Vth1. In some embodiments, the threshold voltage Vth2 is 200 millivolt larger than the threshold voltage Vth1. In some embodiments, the threshold voltage Vth2 is 0.7 volt and the threshold voltage Vth1 is 0.4 or 0.5 volt.

In the embodiments shown in FIG. 2A, when the transistor MP1 and the transistor MP2 are turned on, the voltage V3 (i.e., the voltage at the node n1) and the voltage V4 (i.e., the voltage at the node n2) need to be larger than the threshold Vth1 to turn on the transistor M1 and the transistor M2. In addition, the smaller the threshold voltage Vth1 is, the greater the amplitudes of the voltage V3 and the voltage V4 are and the smaller the offsets of the voltage V3 and the voltage V4 are.

In the embodiments shown in FIG. 2B, when the transistor MN1 and the transistor MN2 are turned on, the voltage V3 (i.e., the voltage at the node n1) and the voltage V4 (i.e., the voltage at the node n2) need to be smaller than the voltage V+ minus the threshold Vth1 to turn on the transistor M1 and the transistor M2. In addition, the smaller the threshold voltage Vth1 is, the greater the amplitudes of the voltage V3 and the voltage V4 are and the smaller the offsets of the voltage V3 and the voltage V4 are.

The resistance value of each resistors of the input buffer 100 can be determined according to requirements as well. In some embodiments, the resistor R1 and the resistor R2 have the same resistance value.

In addition, as mentioned above, the key elements of the input buffer configured to limit the magnitudes of the currents basically involves the connection between the four transistors M1, M2, M3, M4. Furthermore, these limited by the connection approaches for these transistors are actually current ratios. The current control unit 122 can be further introduced to determine the sum of the currents to limit the maximum of the current I3 and the current I4. Furthermore, the application of the connection approaches is not limited to handling the power consumption of the amplifiers. For example, it can be configured for the fabrication of circuit protection devices to limit currents flowing through the circuit to be protected to prevent the circuit from being burned out.

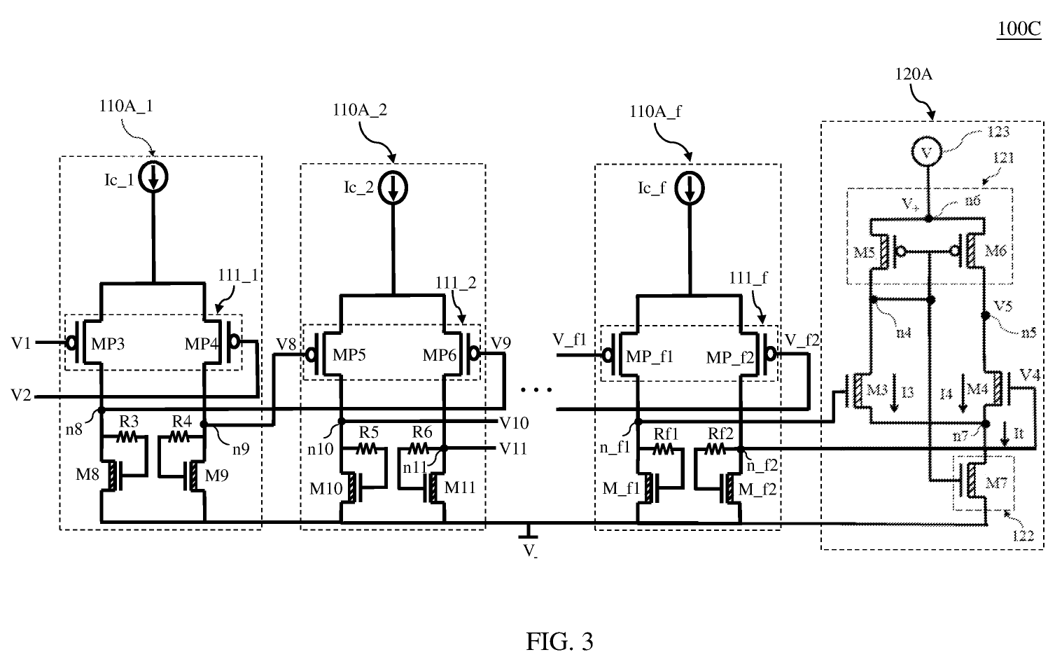

Reference is now made to FIG. 3. FIG. 3 is a schematic diagram of an input buffer 100C, in accordance with some embodiments of the present disclosure. In some embodiments, as shown in FIG. 3, the input buffer 100C includes multiple amplifiers 110A_1, 110A_2…110A_f. In some embodiments, the amplifiers 110A_1, 110A_2…110A_f are configured with respect to the amplifier 110A in FIG. 2A. For example, the amplifier 110A_1 includes a front-end circuit 111_1, resistors R3-R4, transistors M8-M9, in which the front-end circuit 111_1 includes transistors MP3-MP4. The front-end circuit 111_1 is configured with respect to the front-end circuit 111 in FIG. 2A. The transistors MP3-MP4 are configured with respect to the transistors MP1-MP2 in FIG. 2A. The resistors R3-R4 are configured with respect to the resistors R1-R2 in FIG. 2A. The transistors M8-M9 are configured with respect to the transistors M1-M2 in FIG. 2A. The configurations of the amplifiers 110A_2…110A_f are the same as that of the amplifier 110A_1 mentioned above, and thus, repetitious descriptions are omitted here.

As shown in FIG. 3, the amplifiers 110A_1, 110A_2…etc. are coupled sequentially, through corresponding terminals thereof (such as nodes n8, n9, n10, n11…in FIG. 3), to the amplifier 110A_f. For example, drain terminals of the transistors MP3-MP4 of the amplifiers 110A_1 are coupled with gate terminals of the transistors MP5-MP6 at the nodes n8-n9, and so forth.

Furthermore, the amplifier 110A_f is coupled to the amplifier 120A through a node n_f1 and a node n_f2. Specifically, a front-end circuit 111_f of the amplifier 110A_f is coupled with the gate terminal of the transistor M3 and the gate terminal of the transistor M4 at the node n_f1 and the node n_f2, respectively.

In operation, the front-end circuit 111_1 receives the voltage V1 and the voltage V2 of the signals from the transmitting device Tx, and in response to the voltage V1 and the voltage V2 the amplifier 110A_1 generates a voltage V8 and a voltage V9 to the amplifier 110A_2. A front-end circuit 111_2 of the amplifier 110A_2 receives the voltage V8 and the voltage V9, and in response to the voltage V8 and the voltage V9 the amplifier 110A_2 generates a voltage V10 and a voltage V11 to a next-stage amplifier, and so forth. In other words, two adjacent amplifiers of the amplifiers 110A_1, 110A_2…110A_f generate signals associated with the voltage V1 and the voltage V2 with the same approaches as the amplifier 110A_1 and the amplifier 110A_2.

Through the multi-stages amplifiers 110A_1, 110A_2…etc., eventually, a voltage V_f1 and a voltage V_f2 are generated to a front-end circuit 111_f of the amplifiers 110A_f. After the front-end circuit 111_f of the amplifier 110A_f receives the voltage V_f1 and the voltage V_f2, the amplifier 110A_f collaborates with the amplifier 120A to output the voltage V5 at the node n5, in accordance with the operation method of the input buffer 100A mentioned above.

In some embodiments, the signals are further amplified through the amplifier 110A_1, the amplifier 110A_2…the amplifier 110A_f so as to improve the gain.

In some embodiments, the transistors M8-M11, M_f1, M_f2, the transistor M3 and the transistor M4 are of the same conductivity type (e.g., all are P-type transistors or N-type transistors). In some embodiments, the amplifiers 110A_1, 110A_2…110A_f are configured with respect to the amplifier 110B in FIG. 2B, and correspondingly, the amplifier 120A is replaced with the amplifier 120B.

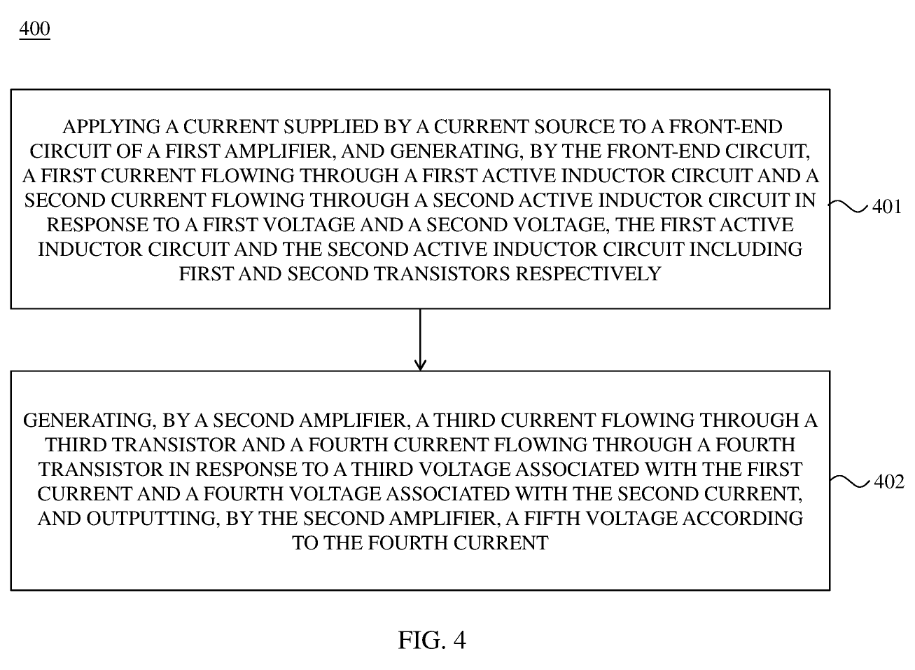

Reference is now made to FIG. 4. FIG. 4 is a flow diagram of an operation method 400 for input buffers of FIG. 1 to FIG. 3, in accordance with some embodiments of the present disclosure. It should be understood that there can be additional operations before, during, and after the process as shown in FIG. 4, and for additional embodiments of the operation method 400, some operations as described as follows can be replaced or eliminated. The operation method 400 includes operations 401-402 described as follows by reference to FIG. 2A to FIG. 3.

In the operation 401, as shown in FIG. 2A, the current Ic is applied to the front-end circuit 111 of the amplifier 110A, and the current I1 following through the transistor M1 and the current I2 flowing through the transistor M2 are generated in response to the voltage V1 and the voltage V2 respectively.

In the operation 402, the current I3 flowing through the transistor M3 and the current I4 flowing through the transistor M4 are generated, through the amplifier 120A, in response to the voltage V3 associated with the current I1 and the voltage V4 associated with the current I2 , and the voltage V5 is outputted according to the current I4 through the amplifier 120A.

In some embodiments, the operation method 400 of the input buffer further includes the operation of applying the voltage supplied by the voltage source 123 to the bias supply circuit 121 to output a bias between the drain terminal of the transistor M3 and the drain terminal of the transistor M4.

In view of the above, the present disclosure indeed provides an input buffer that can broaden the bandwidth and limit the magnitude of the currents, which solves the problem of insufficient bandwidth and high power consumption.

Although the present application has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present application without departing from the scope or spirit of the disclosure. In view of the foregoing, it is intended that the present application cover modifications and variations of this disclosure provided they fall within the scope of the following claims.

What is claimed is:

1. An input buffer, comprising:
a first amplifier, comprising:
a first front-end circuit configured to receive a first voltage and a second voltage;
a first transistor, wherein a first terminal of the first transistor is coupled with the first front-end circuit at a first node; and
a second transistor, wherein a first terminal of the second transistor is coupled with the first front-end circuit at a second node, and a second terminal of the second transistor is coupled with a second terminal of the first transistor at a reference node,
wherein the first amplifier is configured to output, in response to the first voltage and the second voltage, a third voltage and a fourth voltage at the first node and the second node, respectively; and
a second amplifier, comprising:
a third transistor and a fourth transistor, wherein a control terminal of the third transistor and a control terminal of the fourth transistor are coupled with the first amplifier at the first node and the second node, respectively,
wherein the second amplifier is configured to generate a fifth voltage in response to the third voltage and the fourth voltage.

2. The input buffer of claim 1, wherein the first amplifier further comprises:
a first resistor coupled between the first node and a control terminal of the first transistor; and
a second resistor coupled between the second node and a control terminal of the second transistor.

3. The input buffer of claim 2, wherein the first resistor and the second resistor have the same value.

4. The input buffer of claim 1, wherein the first transistor and the second transistor are of the same conductivity type.

5. The input buffer of claim 4, wherein both the first transistor and the second transistor have a first threshold voltage.

6. The input buffer of claim 5, wherein the first front-end circuit comprises:
a transistor pair, wherein a plurality of control terminals of the transistor pair are configured to receive the first voltage and the second voltage, and a plurality of first terminals of the transistor pair are coupled with each other.

7. The input buffer of claim 6, wherein a second threshold voltage of each transistor of the transistor pair is larger than the first threshold voltage.

8. The input buffer of claim 1, wherein the third transistor and the fourth transistor are of the same conductivity type.

9. The input buffer of claim 1, wherein the second amplifier further comprises:
a fifth transistor, wherein a first terminal of the fifth transistor is coupled with a first terminal of the third transistor at a third node; and
a sixth transistor, wherein a first terminal of the sixth transistor is coupled with a first terminal of the fourth transistor at a fourth node,
wherein a second terminal of the fifth transistor and a second terminal of the sixth transistor are coupled with each other.

10. The input buffer of claim 9, wherein the second amplifier further comprises:
a seventh transistor, wherein a first terminal of the seventh transistor is coupled with a second terminal of the fourth transistor, a second terminal of the seventh transistor is coupled to the reference node, and a control terminal of the seventh transistor is coupled with a control terminal of the fifth transistor and a control terminal of the sixth transistor at the third node.

11. The input buffer of claim 1, further comprising:
at least one third amplifier coupled to the first amplifier through first and second terminals of the at least one third amplifier, and configured to generate, in response to a corresponding sixth to seventh voltages received by a second front-end circuit thereof, signals to the first amplifier for generating the first to second voltages,
wherein the at least one third amplifier comprises fifth to sixth transistors coupled to the second front-end circuit at the first and second terminals of the at least one third amplifier.

12. The input buffer of claim 11, wherein the second front-end circuit comprises a seventh transistor and an eighth transistor, and the seventh transistor and the eighth transistor, the third transistor, and the fourth transistor are of the same conductivity type.

13. An input buffer, comprising:
a front-end circuit coupled with a current source;
a first transistor, wherein a drain terminal of the first transistor is coupled with the front-end circuit at a first node;
a second transistor, wherein a drain terminal of the second transistor is coupled with the front-end circuit at a second node,
wherein a source terminal of the second transistor and a source terminal of the first transistor are coupled with each other at a reference node;
a third transistor, wherein a gate terminal of the third transistor is coupled to the first node, and a drain terminal of the third transistor is coupled with a first output terminal of a bias supply circuit at a third node;
a fourth transistor, wherein a gate terminal of the fourth transistor is coupled to the second node, and a drain terminal of the fourth transistor is coupled with a second output terminal of the bias supply circuit at a fourth node; and
a current control unit, wherein the current control unit is coupled with a source terminal of the third transistor and a source terminal of the fourth transistor at a fifth node, and configured to control a total current flowing through the third transistor and the fourth transistor.

14. The input buffer of claim 13, wherein the first transistor, the second transistor, the third transistor, and the fourth transistor are of the same conductivity type.

15. The input buffer of claim 13, wherein both the first transistor and the second transistor have a first size, and both the third transistor and the fourth transistor have a second size which is different from the first size.

16. The input buffer of claim 15, wherein the second size is larger than the first size.

17. The input buffer of claim 13, wherein the current control unit comprises:
a fifth transistor, wherein a drain terminal of the fifth transistor is coupled to the fifth node, a source terminal of the fifth transistor is coupled to the reference node, and a gate terminal of the fifth transistor is coupled to the third node.

18. An operation method of an input buffer, comprising:
applying a current supplied by a current source to a front-end circuit of a first amplifier, and generating, by the front-end circuit, a first current flowing through a first active inductor circuit and a second current flowing through a second active inductor circuit in response to a first voltage and a second voltage, wherein the first active inductor circuit and the second active inductor circuit comprise a first transistor and a second transistor, respectively; and
generating, by a second amplifier, a third current flowing through a third transistor and a fourth current flowing through a fourth transistor in response to a third voltage associated with the first current and a fourth voltage associated with the second current, and outputting, by the second amplifier, a fifth voltage according to the fourth current.

19. The operation method of the input buffer of claim 18, wherein a current ratio of the third current to the first current is associated with a size ratio of a first size of the third transistor to a second size of the first transistor.

20. The operation method of the input buffer of claim 18, further comprising:
applying a voltage supplied by a voltage source to a bias supply circuit to output a bias voltage between a drain terminal of the first transistor and a drain terminal of the second transistor.
